(19) United States
(12) Patent Application Publication
(10) Pub. No.: US 2024/0426880 A1
(43) Pub. Date: Dec. 26, 2024

(54) METHOD FOR MONITORING THE POWER CONSUMPTION OF A MEASURING POINT, AS WELL AS MEASURING POINT AND PROCESS CONTROL SYSTEM

(71) Applicant: Endress+Hauser Conducta GmbH+Co. KG, Gerlingen (DE)

(72) Inventors: Holger Speck, Konstanz (DE); Tilman Benkert, Stuttgart (DE); Stefan Scheller, Filderstadt (DE)

(21) Appl. No.: 18/746,152

(22) Filed: Jun. 18, 2024

(30) Foreign Application Priority Data
Jun. 22, 2023 (DE) 10 2023 116 402.3

(51) Int. Cl. G01R 21/133

(52) U.S. Cl. CPC G01R 21/133

(57) ABSTRACT

A method for monitoring the power consumption of a measuring point with a two-line structure comprises providing the measuring point with a measuring transducer and a sensor, wherein the measuring transducer has a loop input and a loop output connected via a current loop to a control center, wherein the measuring transducer is connected to the sensor for energy and data transmission; determining by the sensor a measured value; outputting by the measuring transducer a transmission current dependent on the sensor measured value at the loop output; determining by the control center a supply voltage provided between the loop input and the loop output of the measuring transducer; determining a supply power from the supply voltage and transmission current; determining a power consumption of the measuring transducer; comparing the power consumption with the supply power; and outputting user information dependent on the comparison.

### CROSS-REFERENCE TO RELATED APPLICATION

The present application is related to and claims the priority benefit of German Patent Application No. 10 2023 116 402.3, filed on Jun. 22, 2023, the entire contents of which are incorporated herein by reference.

### TECHNICAL FIELD

The present disclosure relates to a method for monitoring the power consumption of a measuring point, as well as to a measuring point and a process control system.

### BACKGROUND

In analytical measurement technology, especially in the fields of water management, of environmental analysis, in industry, e.g. in food technology, biotechnology, and pharmaceutics, as well as for the most varied laboratory applications, measured variables, such as the pH, the conductivity, or even the concentration of analytes, such as ions or dissolved gases in a gaseous or liquid measurement medium, are of great importance. These measured variables can be acquired and/or monitored for example by means of electrochemical sensors, such as optical, potentiometric, amperometric, voltammetric, or coulometric sensors, or also conductivity sensors.

The sensor measured values determined by the sensors are processed in so-called measuring transducers. A challenge here, which arises in particular in a potentially explosive environment, is that only a limited level of energy can be provided to the measuring transducer. It is precisely in the potentially explosive area that so-called two-line field devices are often used. Historically, such two-line field devices are predominantly designed such that a current intensity between 4 mA and 20 mA (=milliampere) of the supply current flowing in the single line pair designed as a current loop simultaneously also represents the measured value currently generated by the field device or the measuring point, or the set value currently transmitted to the field device. As a result, a particular problem with such two-line field devices is that the electrical power that can at least be nominally converted or is to be converted by the field device electronics—hereinafter referred to as “available power”—can fluctuate over a wide range during operation. Taking this into account, modern two-line field devices (2L field devices), especially modern two-line measuring devices (2L measuring devices) with a (4 mA to 20 mA) current loop, are therefore usually designed such that their device functionality, implemented by means of a microcomputer provided in the evaluation and operating circuit, is limited thereto, it being possible for this to be carried out at a minimum current value. Some devices also work in such a way that energy-intensive operations of the microcontroller are repeatedly interrupted until an energy store coupled thereto (e.g. a capacitor) is sufficiently filled to continue the operation.

### SUMMARY

It is therefore an object of the present disclosure to propose a method which facilitates the operation of a field device with fluctuating available power.

This object is achieved according to the present disclosure by a method for monitoring the power consumption of a measuring point with a two-line structure.

The method according to the present disclosure comprises the following steps:
providing a measuring point with a measuring transducer and a sensor, wherein the measuring transducer has a loop input and a loop output which are connected via a current loop to a control center for power and data transmission, wherein the measuring transducer is connected to the sensor for energy and data transmission,
determining by the sensor a sensor measured value,
outputting by the measuring transducer a transmission current dependent on the sensor measured value at the loop output,
determining a supply voltage provided between the loop input and the loop output of the measuring transducer by the control center,
determining a supply power on the basis of the supply voltage and the transmission current,
determining a power consumption of the measuring transducer,
comparing the power consumption with the supply power,
outputting user information dependent on the comparison.

The method according to the present disclosure makes it possible for the power consumption of a measuring point to be monitored and provided to the user. This makes it possible to carry out energy-hungry activities at an optimal point in time without impairing the usual measuring operation of the measuring point. In addition, the user can see at a glance the current available supply power or power consumption.

According to one embodiment of the present disclosure, the user information is output at the measuring transducer and/or at the control center after transmission of the user information to the control center, via an output unit.

According to a further embodiment of the present disclosure, in the comparison, it is checked whether the supply power is sufficient for an additional activity of the measuring transducer, wherein the user information contains the result of the check.

According to one embodiment of the present disclosure, in the step of outputting a transmission current dependent on the sensor measurement value, a mathematical mapping is used to determine the transmission current to be output, wherein if the supply power is insufficient for an additional activity, the user information will include a suggestion for a power optimization, wherein the power optimization comprises an adjustment of the mathematical mapping so that a higher transmission current than previous to the adjustment of the mathematical mapping is output for the sensor measurement value. If the maximum transmission current is permitted to be 20 mA, for example in the explosion-proof region, this upper current limit will of course be taken into account in the adjustment.

According to one embodiment of the present disclosure, the method furthermore executes a step of data processing in the measuring transducer and/or wireless communication via a communication module if the supply power is sufficient for an additional activity.

According to one embodiment of the present disclosure, a development over time of excess power based on the comparison is stored and analyzed in the measuring transducer.

According to one embodiment of the present disclosure, the user information indicates a power/time window in which the excess power is sufficient for certain operations of the measuring transducer when the excess power is cyclic over time based on the analysis.

According to one embodiment of the present disclosure, the results of the analysis of the development over time of the excess power are used to determine a point in time for an automatic start of certain operations of the measuring transducer.

The above-described object is also achieved by a measuring point.

The measuring point according to the present disclosure comprises:
a measuring transducer having a loop input and a loop output, wherein the loop input and the loop output are suitable for being connected via a current loop to a control center for power and data transmission,
a sensor which is connected to the measuring transducer for power and data transmission,
wherein the measuring point is suitable for carrying out the method according to the present disclosure.

The aforementioned object is likewise achieved by a process control system.

The process control system according to the present disclosure comprises:
a measuring point according to the present disclosure,
a control center which is connected to the measuring point for energy and data transmission, wherein the measuring transducer and/or the control center has a display unit.

### BRIEF DESCRIPTION OF THE DRAWING

The present disclosure is explained in more detail on the basis of the following description of the figures. In the FIGURES:

FIG. 1 shows a schematic representation of a process control system according to the present disclosure.

### DETAILED DESCRIPTION

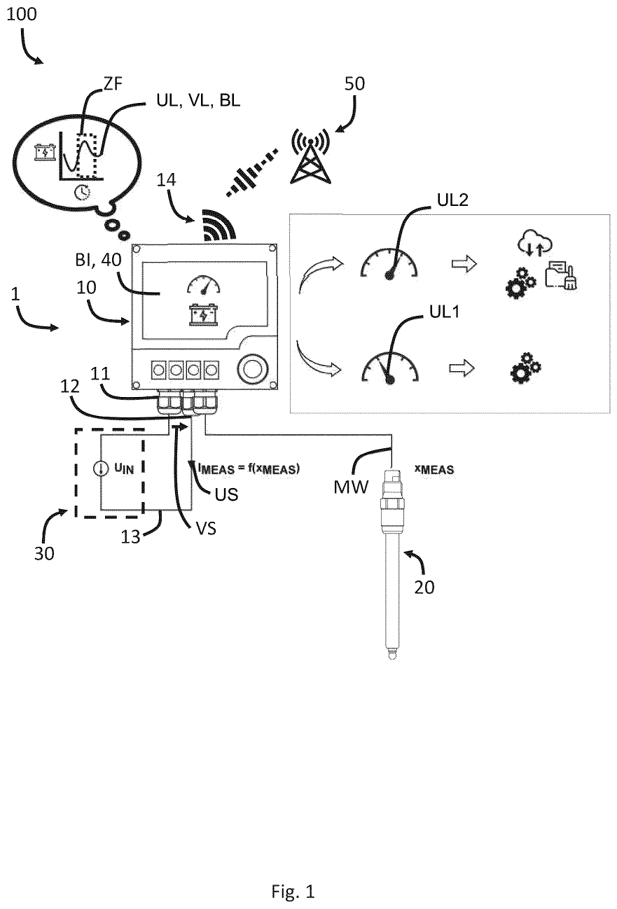

The process control system 100 according to the present disclosure shown in FIG. 1 comprises a measuring point 1 and a control center 30. The measuring point 1 is connected to the control center 30 for energy and data transmission. The measuring point 1 and/or the control center 30 has a output unit 40. The output unit 40 is, for example, a display or another user interface. The control center 30 has a DC voltage source which is characterized in FIG. 1 with UIN. The voltage of the DC voltage source can preferably be regulated.

The measuring point 1 comprises a measuring transducer 10 and a sensor 20 or a device which combines both functionalities. The measuring transducer 10 has a loop input 11 and a loop output 12, wherein the loop input 11 and the loop output 12 are suitable for being connected via a current loop 13 to a control center 30 for power and data transmission. The sensor 20 is connected to the measuring transducer 10 for power and data transmission. The measuring point 1 is a field device or a combination of field devices in which the energy and data are transmitted via one and the same interface. Preferably, the measuring transducer 10 or the measuring point 1 is a two-line field device.

The method according to the present disclosure for monitoring a power consumption of a measuring point 1 is discussed below.

A first step comprises providing the measuring point 1 described above. The measuring transducer 10 is connected via the current loop 13 to the control center 30 for power and data transmission. The current loop 13 preferably permits a current flow of 4 mA to 20 mA.

In a next step, a sensor measured value MW is determined by the sensor 20. In FIG. 1, the sensor measured value MW is also characterized as xMEAS. Depending on the type of sensor 20, the sensor measured value MW is, for example, a voltage (e.g., at a pH sensor) or a resistance value (e.g., at a temperature sensor). The measuring transducer 10 processes the sensor measured value MW so that the sensor measured value MW is transformed into a transmission current US. The transmission current US is between 4 mA and 20 mA. The transmission current US is directly dependent on the sensor measured value MW. The transmission current US is preferably proportional to the sensor measured value MW. The current transmission current US, the development of the transmission current US over time and/or the current sensor measurement value MW, or the development of the sensor measured value MW over time are preferably stored in a memory of the measuring transducer 10.

Next, a step of outputting the transmission current US at the loop output 12 is performed by the measuring transducer 10. Due to the dependence of the transmission current US on the sensor measured value MW, the transmission current US directly forms the sensor measured value MW. This allows the control center 30 to directly infer the sensor measured value MW from the transmission current US. The transmission current US preferably does not exceed 20 mA in order to also be used in potentially explosive environments.

In a further step, a supply voltage VS provided between the loop input 11 and the loop output 12 of the measuring transducer 10 by the control center 30 is determined. The supply voltage VS is preferably equal to the voltage provided by the DC voltage source UIN. However, in an embodiment (not shown), the current loop 13 has additional loads so that the supply voltage VS is lower than the voltage provided by the DC voltage source UIN. The measuring transducer 10 preferably stores the current supply voltage VS and its development over time in the memory.

Next, a step of determining a supply power VL based on the supply voltage VS and the transmission current US takes place. For this purpose, the measuring transducer 10 multiplies the current supply voltage VS by the current transmission current US. The current supply power VL and the development of the supply power VL over time are preferably stored by the measuring transducer 10.

In a following step, the power consumption BL of the measuring transducer 10 is determined. The power consumption BL is the electrical power required by the measuring transducer 10. This comprises the electrical energy which, for example, the sensor 20 requires for operation, or the electrical power required by the measuring transducer 10 for operating the internal control modules such as microprocessor or output units 40 such as status LEDs, display, loudspeakers, data communication by communication module 14, etc. The communication module 14 is suitable for communicating with a communication station 50.

A step of comparing the power consumption BL with the supply power VL is then carried out. In this case, the excess power UL is preferably determined, i.e. a difference between the supply power VL and power consumption BL. Since the supply power VL depends directly on the transmission current US and said current in turn depends on the sensor measured value MW, it can occur under certain measuring conditions that only a small sensor measurement value MW is measured by the sensor 20. With a proportional mapping of the measured sensor value MW onto the transmission current US, this consequently leads to a low transmission current US and therefore to a low supply power VL. In such cases, the excess power UL is only low, which is indicated in FIG. 1 by UL1. In the opposite case, i.e. when a high sensor measured value MW and therefore a high transmission current US and a high supply power VL is present, the excess power UL will also be high, which is indicated in FIG. 1 by UL2. FIG. 1 also shows in a diagram a curve of the excess power UL, i.e. a trend of the excess power UL over time. The curve therefore also indirectly shows the development of the supply power VL and the power consumption BL over time. Of course, it is possible to display the supply power VL and power consumption BL or its progression over time in addition to the excess power UL.

According to one embodiment, in the comparison, it is checked whether the supply power VL is sufficient for an additional activity of the measuring transducer 10. For this purpose, the corresponding power requirements are stored in the measuring transducer 10 for each additional activity. This means that the measuring transducer 10 knows, for example, the additional power consumption of the communication module 14.

Furthermore, there is a step of outputting user information BI dependent on the comparison. The user information BI is output at the measuring transducer 10, and/or at the control center 30 after the user information BI has been transmitted to the control center 30, by means of the output unit 40. As shown in FIG. 1, the current excess power UL, UL1, UL2 is output on a display of the measuring transducer 10, for example. Of course, it is also possible to output the current power consumption BL and/or the current supply power VL separately or simultaneously. For example, a tachometer display is used for the output (see FIG. 1). Of course, it is also possible to output the development over time of the excess power UL and/or the supply power VL and/or the power consumption BL, for example by means of a diagram (see FIG. 1). Preferably, in addition to representing the user information BI, a signal color is used, for example, which allows the user to recognize more quickly whether the supply power VL is sufficient (signal color green), or critical (signal color orange), or too low (signal color red), in order to start or delay energy-hungry activities such as wireless data transmission by the communication module 14 in the measuring transducer 10.

When the above-described check is carried out, the result of the check is preferably output with the user information BI. In particular, if the user desires a data transmission by the communication module 14, but the supply power VL is insufficient to output with the user information BI an error message or warning with/without recommendation.

Preferably, in the step of outputting a transmission current US dependent on the sensor measurement value MW, a mathematical mapping for determining the transmission current US to be output is used. In this case, if the supply power VL is insufficient for an additional activity, the user information BI will include a suggestion for power optimization. The power optimization comprises an adjustment of the mathematical mapping so that a higher transmission current US is output for the sensor measured value MW than before the adjustment of the mathematical mapping,

Wherein, if the supply power VL is sufficient for an additional activity, the method will further execute a step of data processing in the measuring transducer 10 and/or wireless communication via a communication module 14.

According to one embodiment of the method, a development over time of the excess power UL in the measuring transducer 10 is stored and analyzed. In particular, it is checked whether there are repeating, for example, time-dependent progressions of the excess power UL. If there are such cyclic developments over time of the excess power UL, a power time window ZF will be output with the user information BI, in which time window the excess power UL is high enough to carry out certain operations (see FIG. 1). In this power time window ZF, additional activities or operations of the measuring transducer 10 can therefore be carried out well. “Cyclically” is to be understood here to mean that a development of the excess power UL is estimated. For example, the recorded development of the excess power UL is evaluated by an “artificial intelligence” and the future development is estimated. It is therefore possible, for example, to identify patterns during the development of the excess power UL.

The results of the analysis, i.e. in particular the identified power time window ZF, of the development over time of the excess power UL are preferably used to determine a time point for an automatic start of certain activities or operations of the measuring transducer 10. In particular, firmware updates, the exchange of larger quantities of data, for example by the communication module 14 and communication station 50, can be transmitted conveniently and safely.

What is claimed is:

1. A method for monitoring a power consumption of a measuring point with a two-line structure, comprising:
providing a measuring point with a measuring transducer and a sensor, wherein the measuring transducer has a loop input and a loop output which are connected via a current loop to a control center for power and data transmission, wherein the measuring transducer is connected to the sensor for energy and data transmission;
determining by the sensor a sensor measured value;
outputting by the measuring transducer a transmission current dependent on the sensor measured value at the loop output;
determining by the control center a supply voltage provided between the loop input and the loop output of the measuring transducer;
determining a supply power on the basis of the supply voltage and the transmission current;
determining a power consumption of the measuring transducer;
comparing the power consumption with the supply power; and
outputting user information dependent on the comparison.

2. The method according to claim 1, wherein the user information is output at the measuring transducer, and/or at the control center after transmission of the user information to the control center, via an output unit.

3. The method according to claim 1, wherein, in the comparison, it is checked whether the supply power is sufficient for an additional activity of the measuring transducer, wherein the user information contains the result of the test.

4. The method according to claim 3, wherein, in the step of outputting a transmission current dependent on the sensor measurement value, a mathematical mapping for determining the transmission current to be output is used,
wherein if the supply power is insufficient for an additional activity, the user information will include a suggestion for power optimization,
wherein the power optimization comprises an adjustment of the mathematical mapping so that a higher transmission current is output for the sensor measurement value than before the adjustment of the mathematical mapping.

5. The method according to claim 3, wherein if the supply power is sufficient for an additional activity, the method will further execute a step of data processing in the measuring transducer and/or wireless communication via a communication module.

6. The method according to claim 1, wherein a development over time of an excess power based on the comparison is stored and analyzed in the measuring transducer.

7. The method according to claim 6, wherein the user information indicates a power time window in which the excess power is sufficient for certain operations of the measuring transducer when the excess power is cyclic over time based on the analysis.

8. The method according to claim 7, wherein the analysis of the development over time of the excess power is used to determine a point in time for an automatic start of the certain operations of the measuring transducer.

9. A measuring point, comprising:
a measuring transducer having a loop input and a loop output, wherein the loop input and the loop output are suitable for being connected via a current loop to a control center for power and data transmission; and
a sensor which is connected to the measuring transducer for power and data transmission, wherein the sensor is configured to determine a sensor measured value;
wherein the measuring transducer is configured to:
output a transmission current dependent on the sensor measure value at the loop output,
determine a supply voltage provided between the loop input and the loop output,
determine a supply power on the basis of the supply voltage and the transmission current,
determine a power consumption of the measuring transducer,
compare the power consumption with the supply power, and
output user information dependent on the comparison.

10. A process control system, comprising:
a measuring point, including:
a measuring transducer having a loop input and a loop output, wherein the loop input and the loop output are suitable for being connected via a current loop to a control center for power and data transmission; and
a sensor which is connected to the measuring transducer for power and data transmission, wherein the sensor is configured to determine a sensor measured value;
wherein the measuring transducer is configured to:
output a transmission current dependent on the sensor measure value at the loop output,
determine a supply voltage provided between the loop input and the loop output,
determine a supply power on the basis of the supply voltage and the transmission current,
determine a power consumption of the measuring transducer,
compare the power consumption with the supply power, and
output user information dependent on the comparison; and
a control center which is connected to the measuring point for energy and data transmission, wherein the measuring transducer and/or the control center has an output unit.
